(19) United States
(12) Patent Application Publication
(10) Pub. No.: US 2016/0086681 A1
(43) Pub. Date: Mar. 24, 2016

(54) Zone Plate and Method for Fabricating Same Using Conformal Coating

(71) Applicant: Carl Zeiss X-ray Microscopy, Inc., Pleasanton, CA (US)

(72) Inventors: Raymond Leung, Pinole, CA (US); Michael Feser, Orinda, CA (US)

(21) Appl. No.: 14/861,814

(22) Filed: Sep. 22, 2015

Related U.S. Application Data
(60) Provisional application No. 62/054,632, filed on Sep. 24, 2014.

(51) Int. Cl. G21K 1/06; C23C 16/455

(52) U.S. Cl. CPC G21K 1/06; C23C 16/45555

(57) ABSTRACT

A system and method for improving efficiency of zone plates fabricated by conformal layer coatings is disclosed. In embodiments, the inventive conformal layer coating zone plates provide increased zone widths from one times a deposited conformal layer coating thickness up to and including two times the conformal layer coating thickness. By designing a template that increases a mark-to-space ratio of the annular rings of the template, coating sidewalls of the annular rings with an conformal layer coating to form the zones, and then substantially filling annular channels defined by the annular rings with the conformal layer coating to form wider zones, significant efficiency increases can be achieved over conventional conformal layer coating zone plates, especially for innermost zones.

### RELATED APPLICATIONS

This application claims the benefit under 35 USC 119(e) of U.S. Provisional Application No. 62/054,632, filed on Sep. 24, 2014, which is incorporated herein by reference in its entirety.

### BACKGROUND OF THE INVENTION

Lens-based, high-resolution x-ray microscopy largely resulted from research work at synchrotron radiation facilities in Germany and United States starting in the 1980's. While projection-type x-ray imaging systems with up to micrometer resolution have been widely used since the 1930s, ones using x-ray lens with sub-100 nanometer (nm) resolution began to enter the market only this century. These high-resolution microscopes are configured similarly to visible-light microscopes with an optical train typically including an x-ray source, condenser lens, objective lens, and detector.

Because x rays do not refract significantly in most materials, nearly all such x-ray microscopes use diffractive objective lenses, called Fresnel zone plates. A zone plate is a circular grating with linearly decreasing pitch as a function of radius. The grating comprises sets of radially symmetric circular rings separated by annular spaces. The rings are typically fabricated from a material of a high density to maximize the interaction with x-rays by either absorption, phase shift or a combination of both.

Traditionally, zone plates have been manufactured with a multi-level lithographic process to produce high aspect ratio structures that are necessary to produce zone plates with high efficiency. In one example, a silicon nitride membrane layer is deposited with a seed layer of metal, and a thick organic resist layer on top of the seed metal layer is deposited with a thin layer of metal such as titanium to form a hard mask for deep reactive etching. A very thin resist layer is coated on top of the hard mask layer, which is then patterned with the desired widths of the rings and the annular spaces via electron-beam lithography, and developed. The pattern is then transferred into the hard mask by a dry etching step, and the entire structure is transferred into the thick organic resist by highly directional dry etch to form a plating mold. Finally, the structure of the zone plate is created by electroplating into the mold and the mold is removed by dry etching, leaving the zones of the zone plate.

With higher energy x-ray radiation, thicker zone plates are required to achieve optimal efficiency. For example, a zone plate having a thickness of 1650 nanometers (nm) of gold reaches a maximum focusing efficiency of 30.66% at 10 keV. At this same energy, a 350 nm thick zone plate has an efficiency below 3%. Therefore, the challenge of making high resolution and high efficiency zone plate lenses becomes the challenge of making structures with high thickness-to-width aspect ratios, especially with increasing x-ray energy.

The criticality in fabricating thicker zone plates comes in the fabrication and the mechanical stabilization of the outer zones. It is here that the aspect ratios become extreme since the outer zones are the narrowest zones, yet have to be the same height as the other, inner, wider zones. Fabricating these zones challenges existing fabrication processes such as etching and plating technology due to the narrowness of the zones. And then, once fabricated, those high aspect ratio zones can be easily toppled by mechanical stress or other stresses such as charging effects.

A newer zone plate fabrication method uses Atomic Layer Deposition (ALD) to eliminate some of the critical fabrication steps, provide higher aspect ratios and provide higher yields than traditional zone plate manufacturing methods. Atomic Layer Deposition (ALD) Zone plates and fabrication methods are discussed in “Ultra-high resolution zone-doubled diffractive X-ray optics for the multi-keV regime,” Vila-Comamala, J. et al., 3 Jan. 2011, Vol. 19, No. 1, OPTICS EXPRESS 175-184, and “Zone Plate Microscopy to Sub-15 nm Spatial resolution with XM-1 at the ALS,” Chao, W. et al, Proc. 8th Int. Conf. X-ray Microscopy, IPAP Conf. Series 7, pp. 4-6.

In the ALD zone plate fabrication method, a resist layer, typically made of a material with a low refractive index, such as hydrogen silsesquioxane (HSQ), is directly exposed using electron beam lithography and developed to form ring-like HSQ structures as a template for the ALD deposition. Then, zones of the zone plate are formed by conformal coating of a high electron density material, such as a Platinum or Iridium, to the template via ALD. Since the ALD process is a conformal coating process, the deposited metal layer coats both the top, bottom and sidewalls of the template to form the zones of the zone plate. However only the coatings on the sidewalls form the diffractive structures of the zone plate.

ALD zone plate fabrication requires fewer steps, is less complex, improves the quality of outermost zones, and provides a frequency doubling aspect as compared to traditional zone plate plating methods. ALD can also provide an increase in the achievable aspect ratios. The ALD layer can be as thin as a 1 nm and possibly even thinner. Moreover, using a resist layer or template such as HSQ, a straighter sidewall can be obtained as compared to plating methods. The limit to the aspect ratio of ALD zone plates is determined by the straightness of the fabricated sidewalls, i.e. the lateral displacement of the top and bottom of a sidewall has to be less than the coating thickness or zone width.

### SUMMARY OF THE INVENTION

In ideal zone plates, the zones have varying zone widths. The width of the zones increases with decreasing radial distance from the center of the zone plate. And, the width of each zone and its annular space are similar to achieve best focusing efficiency in the first diffraction order. This generally leads to a fixed duty cycle (DCY) of 0.5 across the ideal zone plates, where DCY is a ratio of the width of a given zone and grating period.

Unlike ideal zone plates, conventional ALD zone plates have been constrained to a fixed zone width, which is equal to the thickness of the ALD layer. However, the width of the annular spaces will often increase with decreasing radial distance from the center of the zone plate, as in ideal zone plates. This causes the duty cycle of zones in conventional ALD zone plates to decrease with decreasing radial distance from the center of the zone plate, and therefore, the efficiency of the zones to decrease with decreasing radial distance from the center of the zone plate as compared to ideal zone plates.

As a result, though the ALD process provides many fabrication advantages over traditional methods, by design, conventional ALD zone plates suffer from decreased efficiency by as much as 30% as compared to an ideal zone plate.

The present invention provides a system and method for improving efficiency of ALD zone plates or zone plates fabricated using a similar conformal coating process. Embodiments of the present invention can provide efficiency improvements for zones across all sections of the zone plate, with significant efficiency improvements of up to twice that of conventional ALD zone plates, especially for the zones of innermost sections.

The present invention accomplishes the efficiency increase of the zones of the zone plate by first designing the template to allow for thicker zone widths, from one times a thickness of the conformal (ALD) coating layer up to and including two times the thickness of the conformal coating layer, in one example. The design of the template includes increasing the spatial frequency of the annular rings of the template as compared to conventional ALD zone plates. The spatial frequency of the annular rings is determined by a mark-to-space ratio of the annular rings, which compares the width of the annular rings to the width of annular channels formed by the annular rings of the template.

Then, the ALD or other conformal layer is deposited until it substantially fills at least some of the annular channels between the annular rings, which creates wider zones. The wider zones increase the duty cycle of the zones, which improves their diffraction efficiency as compared to conventional ALD zone plates.

In embodiments, the invention can provide efficiency improvements for zones of inner sections only, or for zones across all sections of the zone plate, including outermost zones, as compared to conventional ALD zone plates.

In general, according to one aspect, the invention features a method for fabricating a zone plate. The method comprises patterning a resist layer to form a template with annular rings that define annular channels, and then depositing a conformal coating layer to form zones of the zone plate on sidewalls of the annular rings, the conformal coating layer substantially filling at least some if not all of the annular channels to form wider zones.

Preferably, depositing the conformal coating layer to form the zones is accomplished using atomic layer deposition (ALD). The resist layer is patterned to form the template, in which the template is designed to have an increasing mark-to-space ratio of the annular rings towards a center of the zone plate over more traditional designs.

Examples of the method use a mark-to-space ratio of Wᵣ-A:A for the annular rings of the template zones located at a local radius r from the center of the zone plate, r being up to ½ times a radius R of the zone plate. A is a thickness of an ALD conformal coating layer, and Wᵣ is an ideal zone width at the local radius r.

A mark-to-space ratio of 1:1 can be used for the annular rings of template zones located at a local radius r from the center of the zone plate, r ranging from where Wᵣ=2A (ideal zone width at radius r equal to two times the ALD coating thickness) up to radius R of the zone plate. This follows the ideal zone plate construction rule.

Preferably, depositing the conformal coating layer to form the zones further includes varying a mark to space ratio of the annular rings of the template to allow zone widths from one times the thickness of the conformal coating layer up, or less, to and including two times the thickness of the conformal coating layer. The thickness of the conformal coating layer is typically chosen to be approximately the width of the outermost zone of an ideal zone plate.

According to one embodiment, the method substantially fills the annular channels with the conformal coating layer for all zones, preferably using a mark-to-space ratio of 1:1 for the annular rings of the outermost zones of the template.

According to another embodiment, the method substantially fills the annular channels with the conformal coating layer for all zones except outermost zones, preferably using a mark-to-space ratio of 1:3 for the annular rings of the outermost zones of the template.

In general, according to another aspect, the invention features a zone plate comprising a grating template including annular rings that define annular channels and a conformal coating layer on the template to form zones of the zone plate, the conformal coating layer substantially filling at least some if not all of the annular channels to form wider zones.

In general according to still another aspect, the invention features a grating device such as possibly an array of linear grating structures, rather than circular structures of a conventional zone plate. The device comprises a template including pillars that define channels and a conformal coating layer on the template to form a grating structures, the conformal coating layer substantially filling at least some if not all of the channels to form wider grating structures.

The above and other features of the invention including various novel details of construction and combinations of parts, and other advantages, will now be more particularly described with reference to the accompanying drawings and pointed out in the claims. It will be understood that the particular method and device embodying the invention are shown by way of illustration and not as a limitation of the invention. The principles and features of this invention may be employed in various and numerous embodiments without departing from the scope of the invention.

### BRIEF DESCRIPTION OF THE DRAWINGS

In the accompanying drawings, reference characters refer to the same or similar parts throughout the different views. The drawings are not necessarily to scale; emphasis has instead been placed upon illustrating the principles of the invention. Of the drawings:

FIGS. 1A and 1B are diagrams of an ideal binary zone plate, where FIG. 1A is a schematic plan view of an ideal binary zone plate partitioned into sections according to their radial distance from the center of the zone plate and FIG. 1B is a cross-sectional view of zones of the zone plate in the sections;

FIGS. 2A and 2B are plots for ideal zone plates that show, as a function of radius, the local efficiency of zones in FIG. 2A, and the weighted efficiency of zones in FIG. 2B;

FIGS. 3A and 3B show diagrams of a conventional atomic layer deposition (ALD) zone plate, where FIG. 3A is a schematic diagram of a conventional (ALD) zone plate similarly partitioned into sections according to their radial distance from the center of the zone plate as in FIG. 1A, and FIG. 3B is a cross-sectional view of zones of the ALD zone plate;

FIGS. 4A and 4B are plots associated with zone efficiency of the conventional ALD zone plates, with FIG. 4A showing duty cycle of the zones as a function of radius, and FIG. 4B showing the local efficiency of the zones as a function of duty cycle;

FIGS. 5A and 5B are plots that compare efficiency of an ideal zone plate and a conventional ALD zone plate, with FIG. 5A showing local efficiency, and FIG. 5B showing weighted efficiency;

FIGS. 6A-6C compare cross-sectional views for the same sections of zone plates, with FIG. 6A showing a cross-sectional view of an ideal binary zone plate, FIG. 6B showing a cross-sectional view of a conventional ALD zone plate, and FIG. 6C showing a cross-sectional view of an ALD zone plate according to one embodiment of the present invention;

FIGS. 7A-7C compare cross-sectional views for the same sections of zone plates, with FIG. 7A showing a cross-sectional view of an ideal binary zone plate, FIG. 7B showing a cross-sectional view of a conventional ALD zone plate, and FIG. 7C showing a cross-sectional view of an ALD zone plate according to a second embodiment of the present invention;

FIGS. 8A-8D are cross-sectional views of a section of the inventive zone plate showing different points in time during deposition of a conformal (ALD) coating layer to form the zones of the zone plate, with FIG. 8A showing initial forming of the zones, FIG. 8B showing some of the annular channels partially filled with the conformal coating layer to begin forming wider zones, FIG. 8C showing substantial filling of the annular channels to form wider zones, and FIG. 8D showing complete filling by the conformal coating layer;

FIGS. 9A and 9B are plots that compare an ideal zone plate, a conventional ALD zone plate, and an inventive zone plate according to the first embodiment shown in FIG. 6C, with FIG. 9A showing efficiency as a function of radius, and FIG. 9B showing weighted efficiency as a function of radius;

FIGS. 10A and 10B are plots that compare an ideal zone plate, a conventional ALD zone plate, and an inventive zone plate according to the second embodiment shown in FIG. 7C, with FIG. 10A showing efficiency as a function of radius, and FIG. 10B showing weighted efficiency as a function of radius;

FIG. 11 is a plot that compares total efficiency (Eₜₒₜ) as a function of transition point radius, when transitioning from the ALD layer coating method according to the embodiment of FIG. 6C to the ALD layer coating method according to the embodiment of FIG. 7C;

FIG. 12 is a plot of optimized zone efficiency for conventional ALD zone plates, showing duty cycle of the zones as a function of radius;

FIGS. 13A and 13B are plots that compare efficiency of an ideal zone plate, and a conventional ALD zone plate optimized for efficiency using concepts of the present invention, with FIG. 13A showing local efficiency, and FIG. 13B showing weighted efficiency;

FIGS. 14A and 14B are plots that compare an ideal zone plate, a conventional ALD zone plate, and an inventive zone plate according to the second embodiment shown in FIG. 7C, where the conventional ALD zone plate and the inventive zone plate have been optimized for efficiency using concepts of the present invention, and where FIG. 14A shows local efficiency as a function of radius, and FIG. 14B shows weighted efficiency as a function of radius; and

FIG. 15 is a schematic side view of an x-ray imaging system in which the inventive zone plates can be used as a condenser and/or objective lens.

### DETAILED DESCRIPTION OF THE PREFERRED EMBODIMENTS

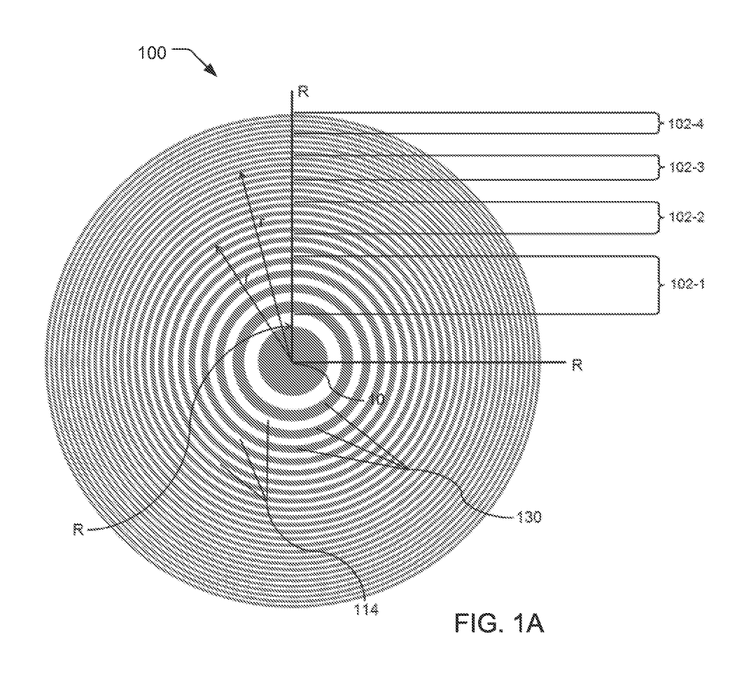

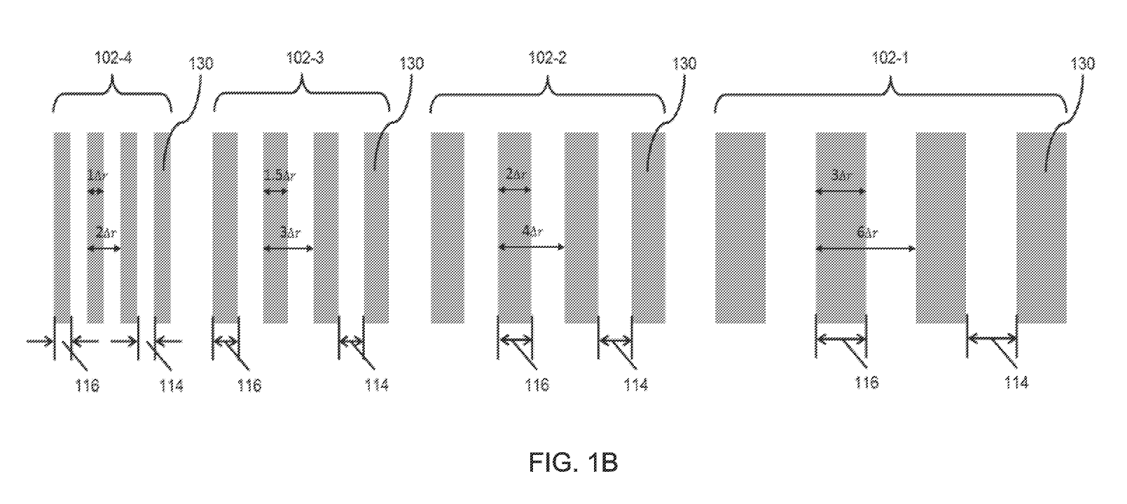

FIG. 1A shows an ideal binary zone plate 100 notionally partitioned into sections 102. The sections 102 include zones 130 and annular spaces 114 separating the zones.

The distance between the center 10 of the zone plate to any given zone 130 is referred to as the local radius r of the zone. In general, the efficiency of each zone can be expressed as a function of its local radius r, the radius of the zone plate R, and its duty cycle.

FIG. 1B shows a cross-section of zones of the exemplary ideal zone plate as shown in FIG. 1A in each of the sections. Within each section the duty cycle is illustrated to be constant. The zones 130 appear as rectangles in the cross-section, but they extend in three dimensions in a circular fashion to form rings. As shown, the width 116 of the zones increases with decreasing radial distance from the center of the zone plate, the width of the annular spaces 114 increases by the same amount. As a result, the zones 130 have the same DCY of 0.5 across all sections 102 of the zone plate, which maximizes efficiency in the first diffraction order of the zones 130 in each section 102.

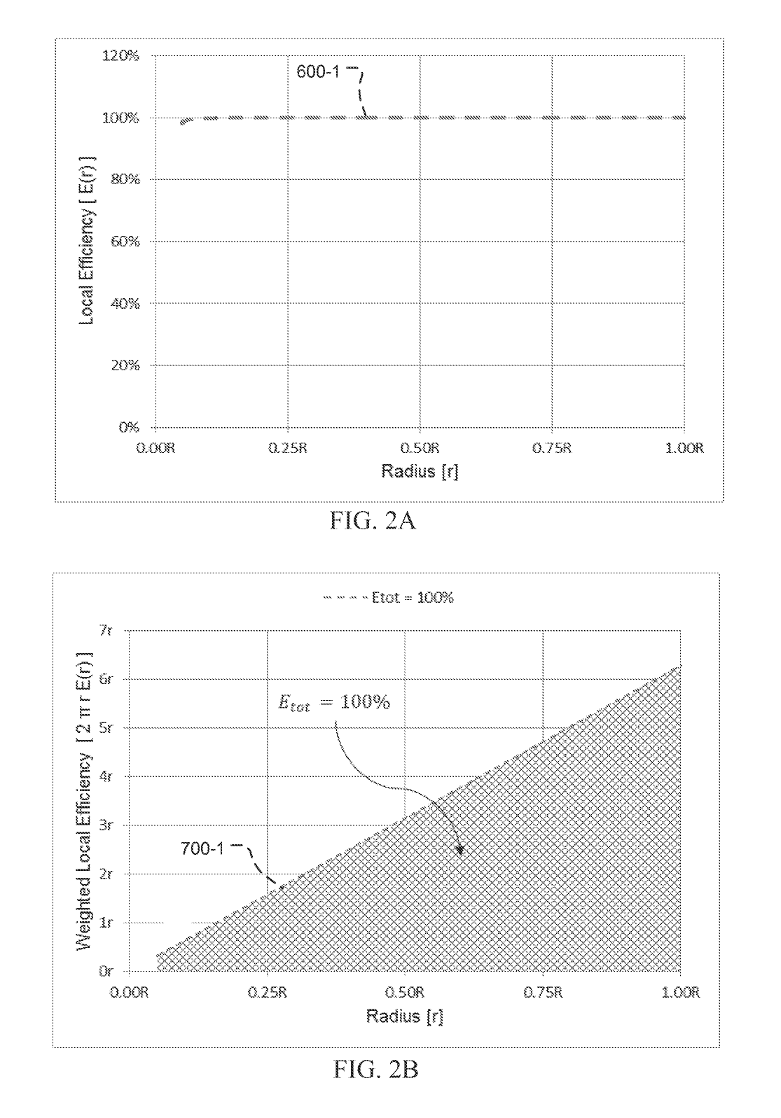

FIG. 2A plots the local first diffraction order efficiency E(r) of the zones 130 of an ideal zone plate as a function of local radius r and duty cycle DCY, according to

E(r)=sin² (πDCY(r))

Because the duty cycle is the same optimum value of 0.5 across all zones 130 in the ideal zone plate, the local efficiency 600-1 of zones 130 in an ideal zone plate simplifies to E(r)=sin²(π0.5), or E(r)=1 for all r. The efficiency E(r) in this figure and the following is the efficiency relative to an ideal binary zone plate.

FIG. 2B plots the radially weighted efficiency (2πrE(r)) of ideal zone plates as a function of local radius r. This accounts for the varying efficiency contributions of different local radii r whereas increasing local radii has increasing efficiency contribution. From this, the total efficiency is calculated by integrating over r and normalizing over the area of the zone plate (πR²) according to:

$${E}_{tot} = \frac{1}{π {R}^{2}} {\int }_{0}^{R} 2 π rE ( r ) d r$$

Because E(r)=1 for all r for the ideal zone plate, this simplifies

$${E}_{tot} = \frac{1}{π {R}^{2}} {\int }_{0}^{R} 2 π r d r = 1 , or {E}_{tot} = 100 \%$$

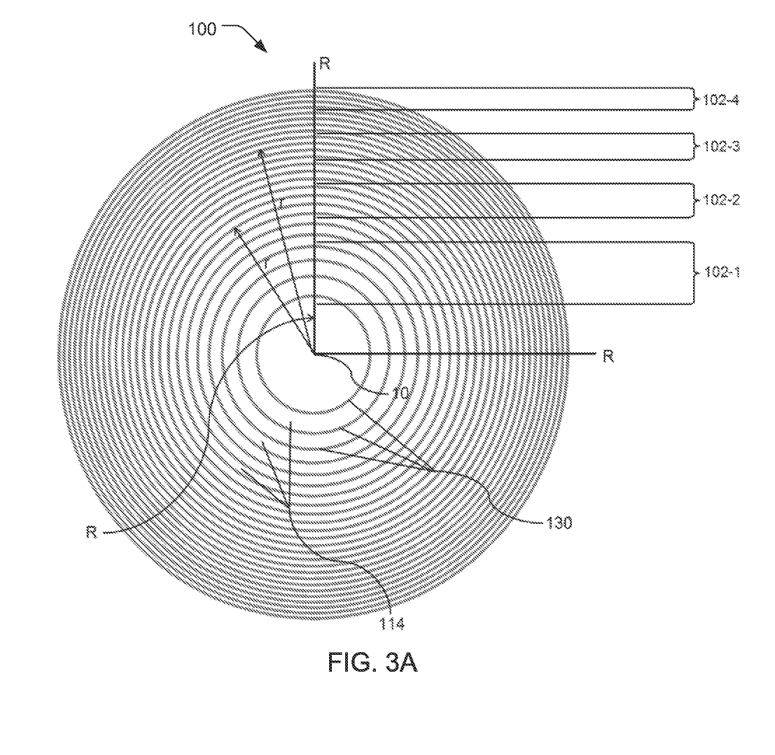

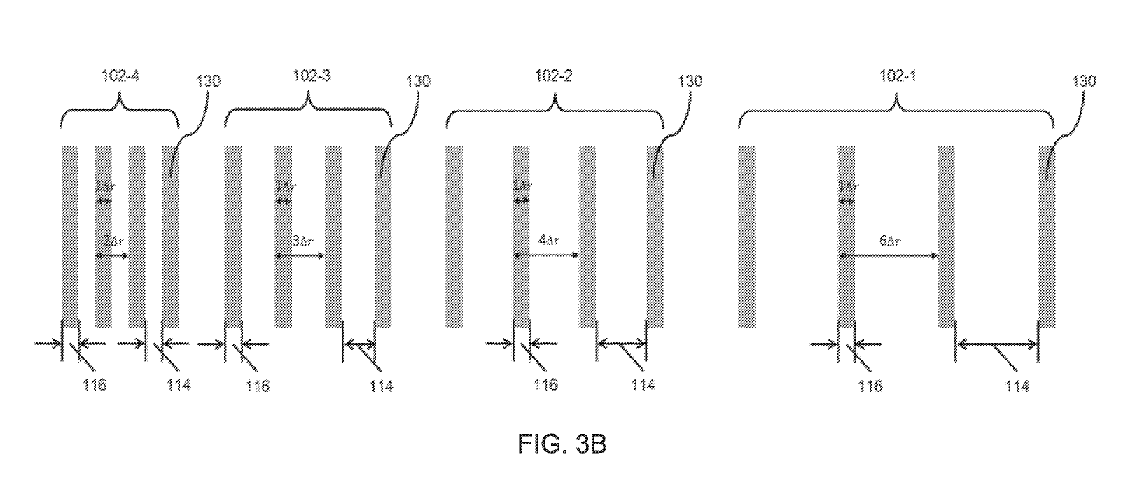

FIG. 3A shows a conventional ALD zone plate. It is similarly partitioned into notional sections 102 as in the ideal zone plate in FIG. 1A. Due to limitations of the fabrication methods utilized, however, the zones 130 have the same width 116 across all sections 102, which is equal to the width of the ALD layer. The zone width 116 of the zones 130 in most sections 102 is less than that of the ideal zone plate 100, yet the width of the annular spaces 114 similarly increases with decreasing distance from the center 10 of the zone plate, as in the ideal zone plate.

As a result, the DCY decreases for the inner zones, and therefore the diffraction efficiency decreases for the inner zones as compared an ideal zone plate. This is especially the case for the zones 130 of the first inner section 102-1, the zones 130 of which are noticeably thinner in width 116 than the corresponding zones 130 of the first inner section 102-1 of the ideal binary zone plate of FIG. 1A.

FIG. 3B shows a cross-section of zones 130 for the conventional ALD zone plate as shown in FIG. 3A. As in FIG. 1B, the zones 130 appear as rectangles in the cross-section, but they extend in three dimensions in a circular fashion to form rings. Unlike the ideal zone plate of FIG. 1B, however, the zones 130 all have the same width, but their adjacent annular spaces 114 increase with decreasing radial distance from the center 10 of the zone plate. As a result, the DCY of zones decreases with decreasing radial distance from the center 10 of the zone plate, and therefore, the efficiency of the zones decreases as compared to the ideal zone plate.

For example, FIG. 3B includes exemplary normalized values for zone widths 116 and annular spaces 114 for different sections 102 of the zone plate. For the zones of sections 102-4, 102-3, 102-2, and 102-1, the zone widths 116 compared to the widths of the annular spaces 114 are on the order of 1:1, 1:2, 1:3, and 1:5, respectively. This corresponds to local DCY values on the order of 0.5 0.33, 0.25, and 0.167 respectively.

Compared to the ideal zone plate in FIG. 1B, which has a DCY value of 0.5 across all zones, the efficiency of the zones 130 for the conventional ALD zone plate decreases for all zones except for zones located in outermost section 102-4.

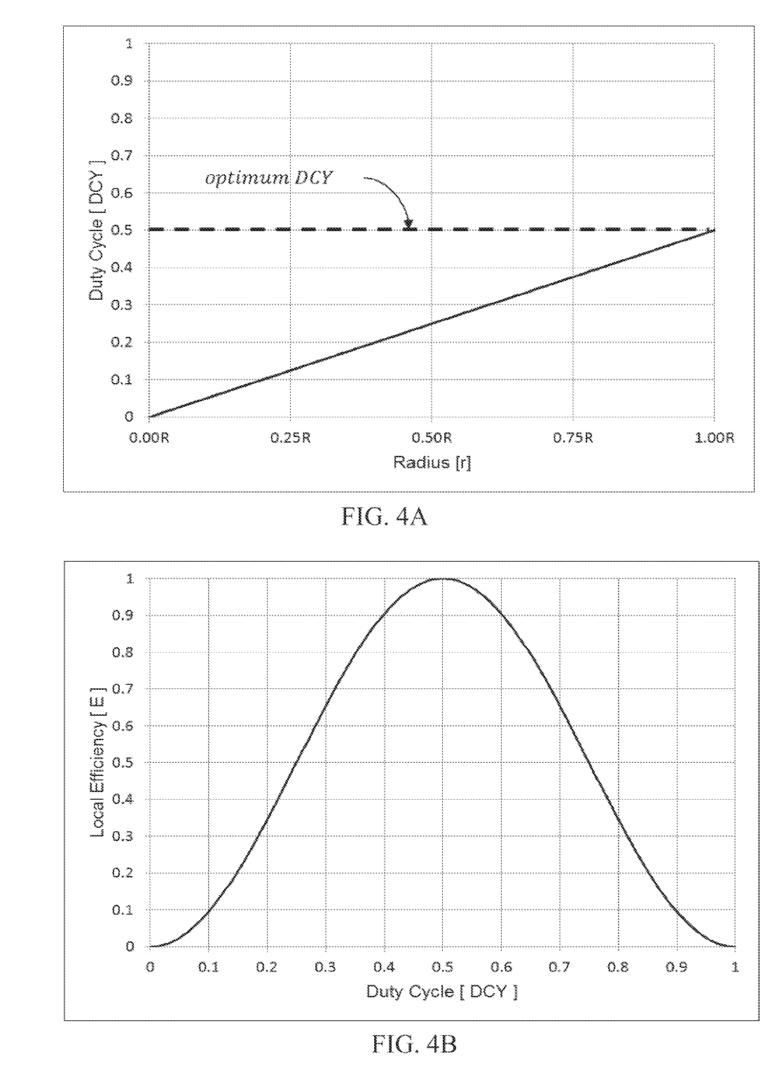

FIG. 4A plots the DCY for the zones 130 of conventional ALD zone plates. The DCY varies linearly with radius according to

$$DCY ( r ) = \frac{0.5 r}{R} .$$

FIG. 4B plots the local efficiency E(r) of the zones 130 as a function of duty cycle and local radius r of each zone, according to E(r)=sin² (πDCY(r)).

FIGS. 5A and 5B compare, for both the ideal zone plate of FIG. 1A and the conventional ALD zone plate of FIG. 3A, the local diffraction efficiency E(r) of the zones as a function of local radius, in FIG. 5A, and the weighted efficiency as a function of the local radius, in FIG. 5B.

FIG. 5A shows local efficiency E(r) curves 600-1 and 600-2 for the ideal and conventional ALD zone plates, respectively. For the conventional ALD zone plate, the local efficiency E(r) as a function of radius r is E(r)=sin² (πDCY(r)), which simplifies to

$$E ( r ) = {sin}^{2} ( π \frac{0.5 r}{R} ) .$$

FIG. 5B compares the total or weighted efficiency 700-1 and 700-2 for the ideal and conventional ALD zone plates, respectively. The total efficiency of zone plates, normalized over the area of the zone plate (πR²), in general,

$${E}_{tot} = \frac{1}{π {R}^{2}} {\int }_{0}^{R} 2 π rE ( r ) d r ,$$

calculated for conventional ALD zone plates is:

$${E}_{tot} = \frac{1}{π {R}^{2}} {\int }_{0}^{R} 2 π r {sin}^{2} ( π \frac{0.5 r}{R} ) d r = 0.703 , or$$

$${E}_{tot} = 70.3 \% .$$

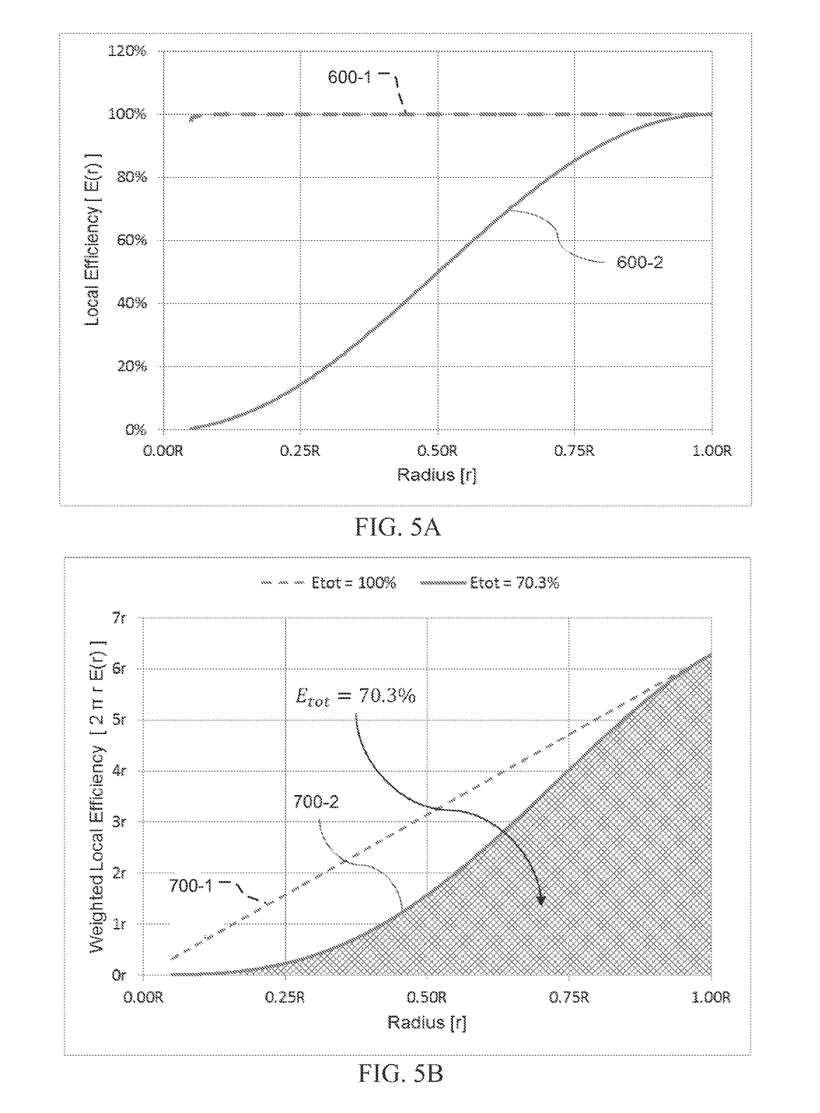

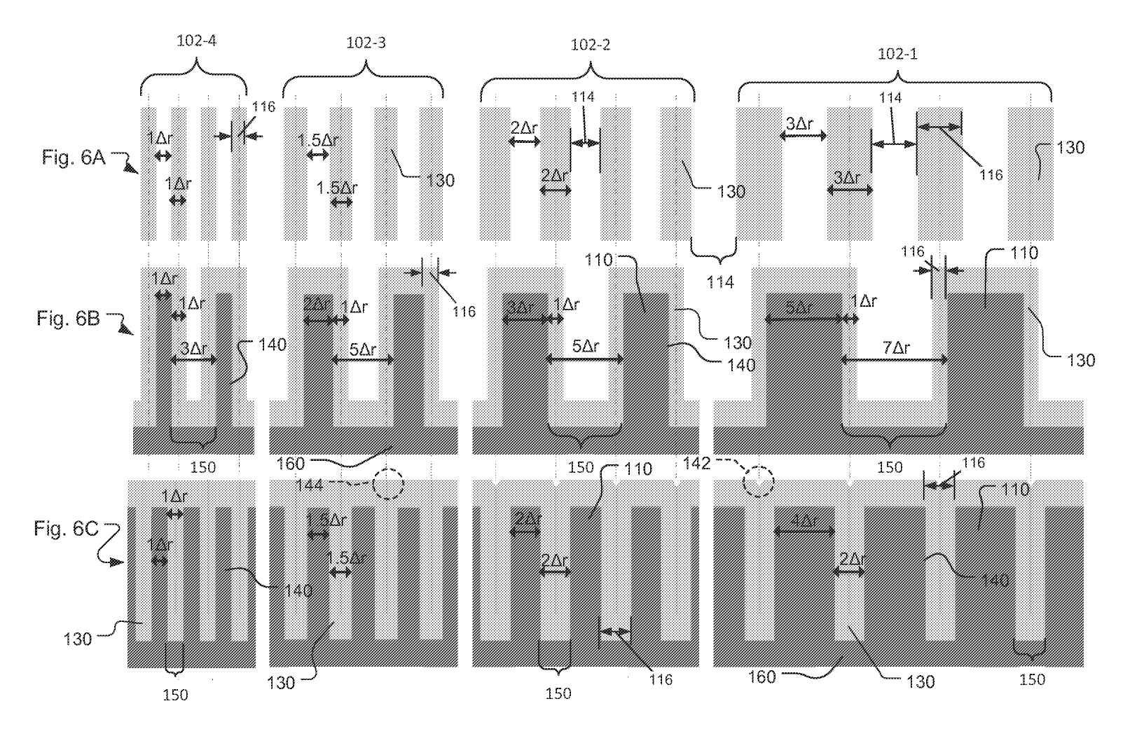

FIGS. 6A-6C compare cross-sectional views for the same sections 102 of three different zone plates 100. The figures compare cross-sections of zones of an ideal binary zone plate in FIG. 6A, cross-sections including zones and a template 160 of a conventional ALD zone plate in FIG. 6B, and cross-sections including zones and a template 160 of an inventive ALD zone plate constructed according to a first embodiment of the present invention in FIG. 6C.

Of the sections, there is an outermost section 102-4, a third inner section 102-3, a second inner section 102-2, and a first inner section 102-1. For each section 102, the ideal zone width 116 of the zones 130 is a multiple of Δr, the zone width of the outermost zones. The ideal zone width at local radius r is also known as Wᵣ.

The first inner section 102-1 includes zones having a local radius r on the order of ⅓ times the radius R of the zone plate, measured from the center 10 of the zone plate 100. The zone widths 116 of the zones 130 in the first inner section 102-1 are on the order of 3 times Δr. The zones 130 of the first inner section 102-1 are also referred to as innermost zones.

A second inner section 102-2 includes zones having a local radius r on the order of ½ times R measured from the center 10 of the zone plate. The zone widths 116 of the zones 130 in the second inner section 120-2 are on the order of 2 times Δr.

A third inner section 102-3 includes zones having a local radius r on the order of ⅔ R measured from the center 10 of the zone plate 100. Finally, an outermost section 102-4, associated with outermost zones, includes zones having a local radius r on the order of R measured from the center 10 of the zone plate 100.

For all zone plates, the ideal zone widths Wᵣ (r) as a function of local radius r for zones 130 in each of the sections 102 are as follows:
Wᵣ (r)≈1 Δr for the zones 130 of outermost section 102-4, where the zones 130 have a local radius r≈R;
Wᵣ (⅔r)≈1.5 Δr for the zones third inner section 102-3, where the zones 130 have a local radius r≈0.67R;
Wᵣ (½r)≈2 Δr for the zones 130 of second inner section 102-2, where the zones 130 have a local radius r≈0.5R; and
Wᵣ (⅓r)≈3 Δr for the zones 130 of first inner section 102-1, where the zones 130 have a local radius r≈0.33R.

FIG. 6B shows a cross-section of a conventional ALD zone plate. The ALD fabrication process first patterns a resist layer, typically hydrogen silsesquioxane (HSQ), to form a template 160. The template 160 includes resist annular rings 110 that provide underlying support for zones 130 that the ALD process deposits on the sidewalls 140 of the annular rings 110. The annular rings 110 also define annular channels 150 of the template 160 between the annular rings 110. Finally, the conformal nature of the ALD layer means that it is deposited with a generally uniform thickness across the zone plate, the ALD layer coating the sidewalls 140 of the annular rings 110 to form the zones 130 in all sections 102. The annular rings 110 appear as narrow rectangles in the cross-section, but they extend in three dimensions in a circular fashion to form rings of HSQ resist material.

The template 160 has a mark-to-space ratio of the annular rings that compares the width of annular rings 110 to the width of their annular channels 150. The mark-to-space ratio of the annular rings 110 is selected with a priori knowledge of the thickness of the ALD layer. This is because the mark-to-space ratio of the annular rings 110 is both a function of the thickness of the ALD layer, A, and the ideal zone width Wᵣ at local radius r for the zones 130 of each section 102.

Conventional ALD zone plates have an optimum mark width of (2Wᵣ−A) and an optimum space width of (2Wᵣ+A) for the annular rings 110 of the template 160, where A is the thickness of the ALD conformal coating layer and Wᵣ is the ideal zone width at local radius r. As a result, the mark-to-space ratio of the annular rings 110 decreases with increasing radial distance from the center 10 of the zone plate. At the same time, the zone width 116 of all zones 130 is fixed by the thickness of the ALD layer. This causes the duty cycle of the zones 130 to decrease with decreasing radial distance from the center 10 of the zone plate for zones 130 of inner sections 102-3 through 102-1, and therefore, the efficiency to decrease as compared to the ideal zone plate.

FIG. 6C shows a cross-section of an improved ALD zone plate according to one embodiment. The resist layer is similarly patterned to form the annular rings 110 of the template 160 as in the conventional ALD zone plate case of FIG. 6B, with the exception that the mark-to-space ratio of the annular rings 110 is increased across all sections 102, including outermost sections 102-4. This increases the spatial frequency of the annular rings 110 in each section 102, or number of annular rings per section 102, as compared to conventional ALD zone plates.

To overcome the limitation of fixed zone widths in conventional ALD zone plates, the conformal coating layer is then deposited until the ALD coating substantially fills the annular channels 150. When viewed in a cross-section or slice, the annular rings 110 are slightly trapezoidal in shape, being slightly wider at the bottom and thinner at the top. This minimizes the possibility of the annular channels 150 becoming “pinched off” at the top before being substantially filled by the conformal coating layer. The annular channels 150 are substantially filled when the sidewalls 140 of adjacent annular ring 110 meet and are pinched off, as indicated by reference 142, thus forming wider zones.

This can provide an increase in the zone width 116 of the zones 130 from a value of 1 times A, up to and including 2 times A, as compared to conventional ALD zone plates.

This embodiment increases the mark-to-space ratio of the annular rings 110 of outermost zones. Because the annular rings 110 of outermost zones were already thin and also had the highest aspect ratios in conventional ALD zone plates, this embodiment increases fabrication challenges and eliminates the advantage of frequency doubling as compared to conventional ALD zone plates.

The ALD layer can additionally be deposited beyond the point of substantially filling the annular channels 150, allowing the ALD layer to accumulate on the tops of the annular rings 110 and the annular channels 150. This is indicated by reference 144. This additional accumulation of material can act as a thin filter, in examples.

Of the sections 102, outermost section 102-4 and third and second inner sections 102-3 and 102-2, respectively, can achieve full density 1:1 zone mark-to-space ratios of the annular rings 110 up to zone widths 116 of two times the conformal coating layer thickness, A. This corresponds to an optimum duty cycle of 0.5 for the zones 130 in sections 102-4, 102-3, and 102-2. For first inner section 102-1, the innermost section, the optimum mark-to-space ratios of the annular rings 110 is according to (Wᵣ−A): A, with the width of the annular channels 150 at a constant value of 2 times A across the zones of section 102-1. This optimizes the mark-to-space ratio of the annular rings 110 for zone widths of 2 Δr for the zones 130 of first inner section 102-1.

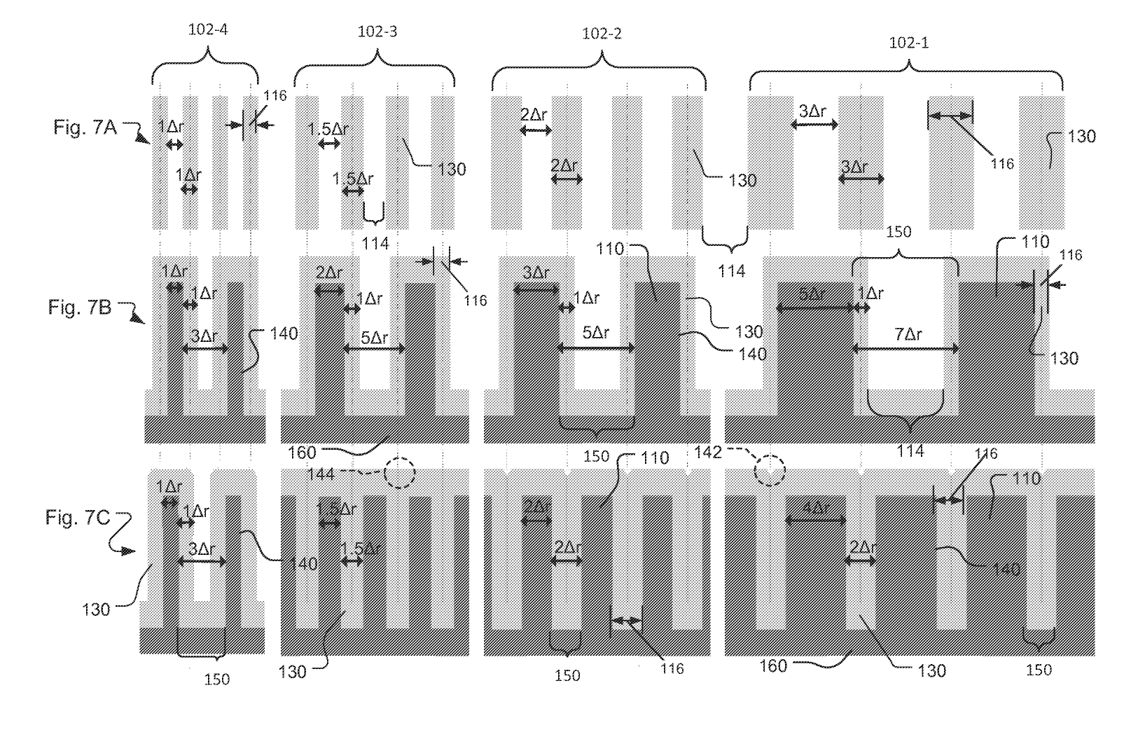

FIGS. 7A-7C compare substantially similar cross-sectional views for the same sections 102 of three different zone plates 100 as in FIGS. 6A-6C. The figures compare cross-sections of an ideal binary zone plate in FIG. 7A, a conventional ALD zone plate in FIG. 7B, and an improved ALD zone plate constructed according to another embodiment of the present invention in FIG. 7C.

FIG. 7C shows a cross-section of an improved ALD zone plate according to another, second, embodiment. Here, the resist layer is similarly patterned to form the annular rings 110 of the template 160 for inner sections 102-3 through 102-1 as in the embodiment of FIG. 6C. The embodiment uses the same high-density HSQ template 110 mark-to-space ratio, or spatial frequency of the annular rings 110, for the inner sections 102-3 through 102-1 as in the embodiment of FIG. 6C.

The outermost section 102-4, however, uses the same mark-to-space ratio of the annular rings 110 as that of the outermost section 102-4 of the conventional ALD zone plate of FIG. 7B. The embodiment of FIG. 7C is a simpler case and is easier to fabricate than that of FIG. 6C. Compared to the embodiment of FIG. 6C, the current embodiment similarly increases the efficiency of the zones 130 across all inner sections 102-3 through 102-1 while avoiding the fabrication complexity associated with increasing the spatial frequency of the annular rings 110 of the template 160 for the zones 130 of outermost section 102-4.

The second embodiment provides wider zones as compared to the conventional ALD zone plate in FIG. 7B, with up to twice the ALD layer coating depth or thickness for the inner zones which are zones associated with sections 102-1, 102-2, and 102-3. For the outer zones, in section 102-4, the spacing of annular rings 140 is arranged so that the width of the annular channels 150 exceeds the ALD layer thickness. The consequence is that the annular channels 150 are not filled but the sidewalls 140 of the annular rings 160 are coated. This provides the frequency doubling effect found in conventional ALD zone plates.

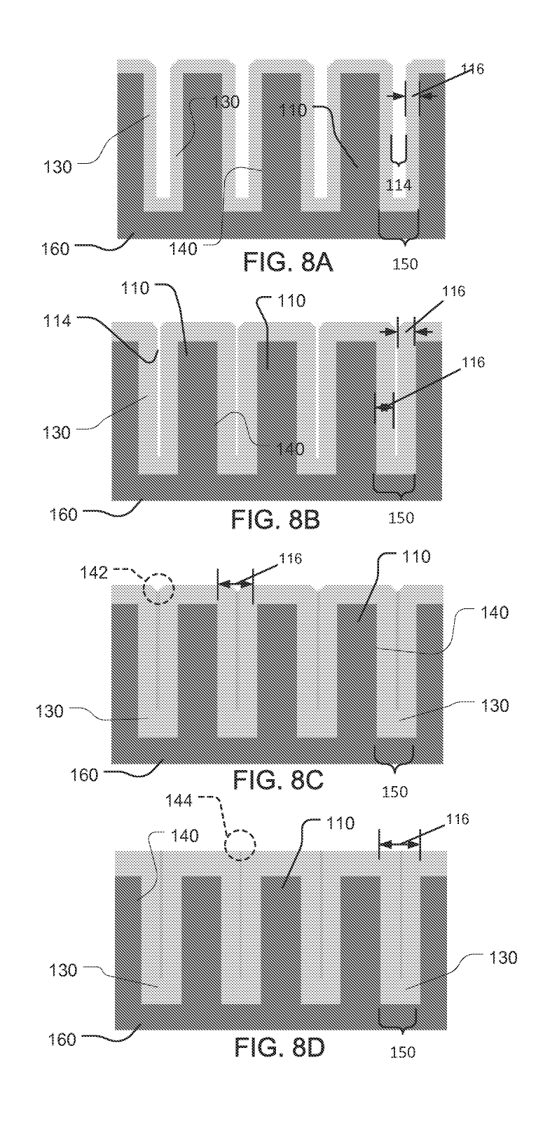

FIGS. 8A-8D show cross-sectional views according to embodiments of the inventive zone plate at different times or phases when depositing the conformal coating layer to form wider zones 130. FIG. 8A provides a view of the deposition process at the point where the sidewalls 140 are initially coated, as during the formation of zones 130 for conventional ALD zone plates as in FIGS. 6B and 7B.

FIG. 8B shows the beginning of the process that substantially fills the annular channels 150 with the conformal coating layer. The conformal coating layer has been additionally deposited within the annular channels 150 almost to the point where the sidewalls 140 of adjacent annular rings 110 meet or are pinched off. The notion of annular spaces 114 between zones 130, as in ideal and conventional ALD zone plates, begins to disappear.

FIG. 8C shows substantial filling of the annular channels 150, where the sidewalls 140 now meet and are pinched off to form maximum width zones 130. Finally, FIG. 8D shows excess accumulation of the conformal coating layer on top of the annular rings 110 and annular channels 150. In examples, the accumulated conformal coating layer acts as a thin negligible filter.

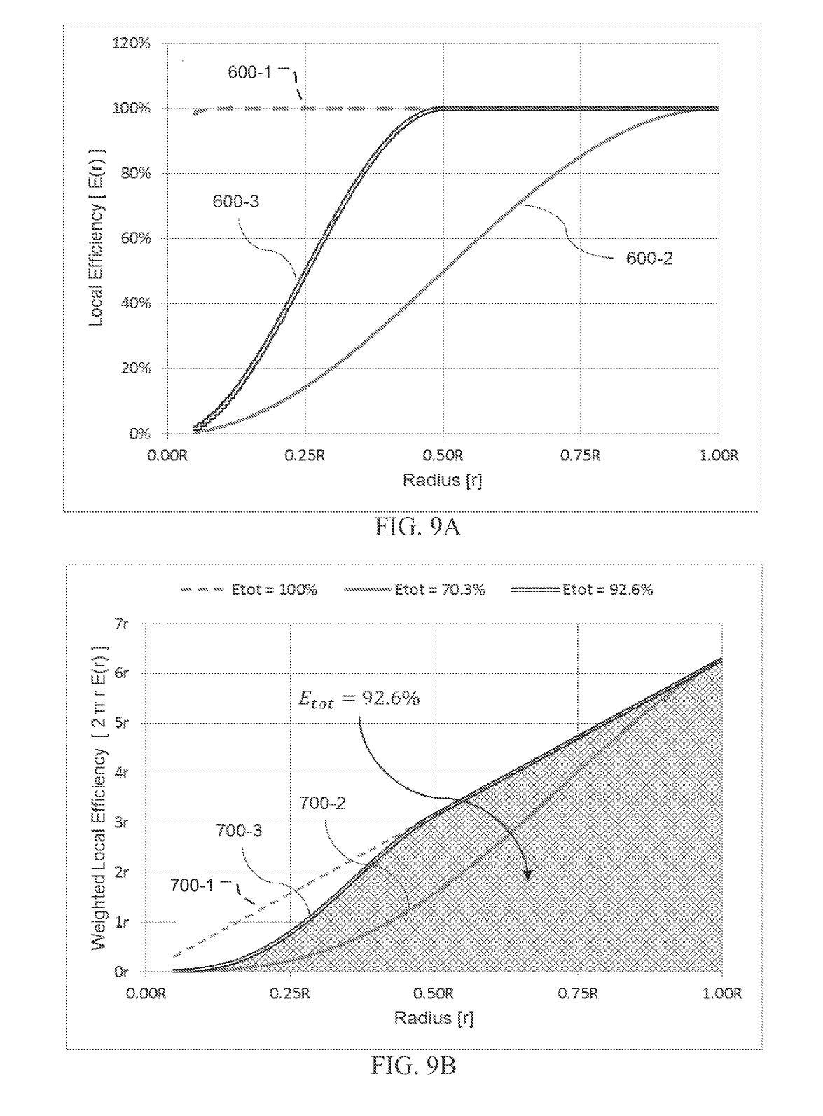

FIGS. 9A and 9B compare the diffraction efficiency, in FIG. 9A, and weighted diffraction efficiency, in FIG. 9B, for ideal, conventional ALD zone plates, and an inventive ALD zone constructed according to the first embodiment of FIG. 6C.

In FIG. 9A, local efficiency curves of the ideal zone plate 600-1, conventional ALD zone plates 600-2, and the inventive ALD zone plate 600-3 according to the embodiment of FIG. 6C are compared. A zone plate 100 constructed according to this embodiment not only significantly improves the diffraction efficiency of zones 130 of inner sections 102-1 through 102-3 as compared to conventional ALD zone plates, but also allows the efficiency of the inventive zone plate 100 to approach that of an ideal binary zone plate in multiple sections 102. Specifically, the efficiency for zones 130 of the inventive zone plates approaches or matches that of the ideal zone plate for zones 130 with a local radius r of approximately 0.5R to R, which corresponds to zones in sections 102-3 through 102-1.

FIG. 9B shows weighted efficiency curves for the ideal zone plate 700-1, conventional ALD zone plate 700-2, and the inventive zone plate 700-3 constructed according to the embodiment of FIG. 6C.

In FIG. 9A and 9B, the local efficiency E(r) is:

$$E ( r ) = {sin}^{2} ( π DCY ( r ) )$$

$$E ( r ) = {sin}^{2} ( π \frac{0.5 r}{0.5 R} ) where 0 < r < 0.5 R$$

$$E ( r ) = 1 where 0.5 R < r < R$$

and the total efficiency, normalized over the area of the zone plate (πR²), Eₜₒₜ is:

$${E}_{tot} = \frac{1}{π {R}^{2}} {\int }_{0}^{0.5 R} 2 π r {sin}^{2} ( π \frac{0.5 r}{0.5 R} ) d r + \frac{1}{π {R}^{2}} {\int }_{0.5 R}^{R} 2 π r d r = 0.926$$

$${E}_{tot} = 92.6 \%$$

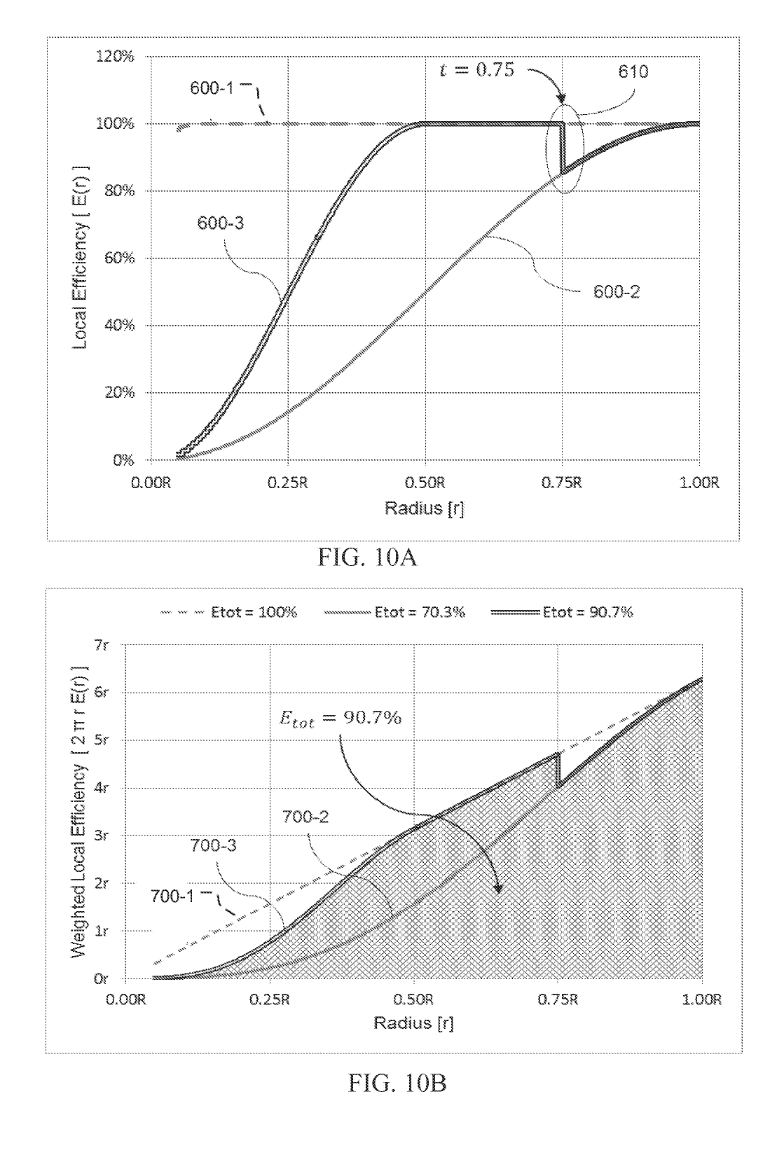

FIGS. 10A and 10B compare the diffraction efficiency, in FIG. 10A, and weighted diffraction efficiency, in FIG. 10B, for ideal, conventional ALD zone plates, and an inventive ALD zone constructed according to the second embodiment of FIG. 7C.

FIG. 10A shows substantially similar efficiency plots 600-1 and 600-2 as that of FIG. 5A, instead showing efficiency curve 600-3 for the embodiment of FIG. 7C. Because the annular rings 110 of the template 160 are fabricated so a discontinuity arises when the zones change from being fabricated by filling the annular channels (sections 102-1 through 102-3) to merely coating the sidewalls of the annular rings (section 102-4), a jump 610 in the efficiency curve 600-3 occurs. The location of the discontinuity spike 610, tR, is determined by fabrication limitations and is experimentally inferred based on process capability. This example shows the transition point at 0.75R (t=0.75).

In a similar fashion, FIG. 10B shows weighted efficiency curves for the ideal zone plate 700-1, conventional ALD zone plate 700-2, and the inventive zone plate 700-3 constructed according to the embodiment of FIG. 7C.

In FIGS. 10A and 10B, the local efficiency E(r) is:

$$E ( r ) = {sin}^{2} ( π DCY ( r ) )$$

$$E ( r ) = {sin}^{2} ( π \frac{0.5 r}{0.5 R} ) where 0 < r < 0.5 R$$

$$E ( r ) = 1 where 0.5 R < r < tR$$

$$E ( r ) = {sin}^{2} ( π \frac{0.5 r}{R} ) where tR < r < R$$

and the total efficiency, normalized over the area of the zone plate (πR²), Eₜₒₜ is:

$${E}_{tot} = \frac{1}{π {R}^{2}} {\int }_{0}^{0.5 R} 2 π r {sin}^{2} ( π \frac{0.5 r}{0.5 R} ) d r + \frac{1}{π {R}^{2}} {\int }_{0.5 R}^{tR} 2 π r d r + \frac{1}{π {R}^{2}} {\int }_{tR}^{R} 2 π r {sin}^{2} ( π \frac{0.5 r}{R} ) d r$$

$${E}_{tot} = 0.907 for t = 0.75$$

$${E}_{tot} = 90.7 \% for t = 0.75$$

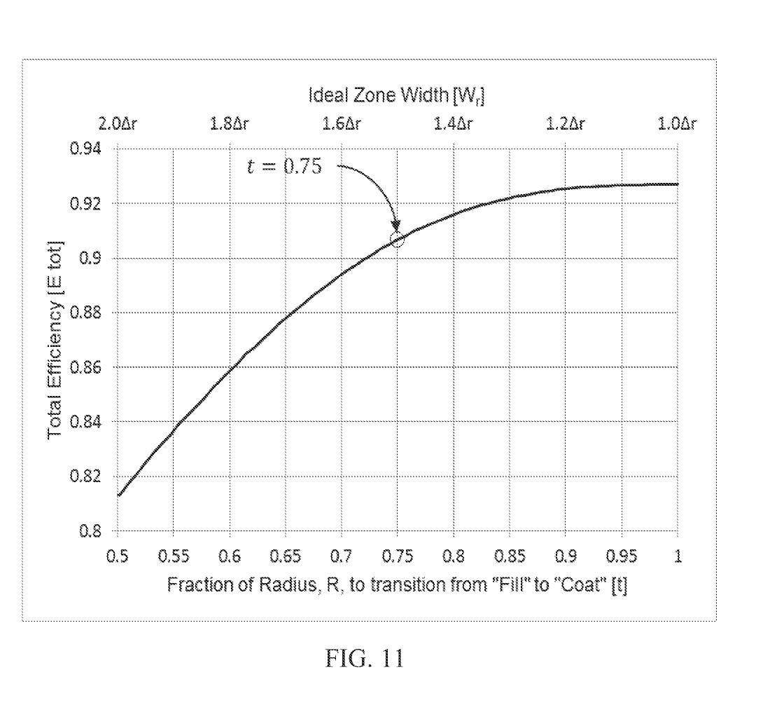

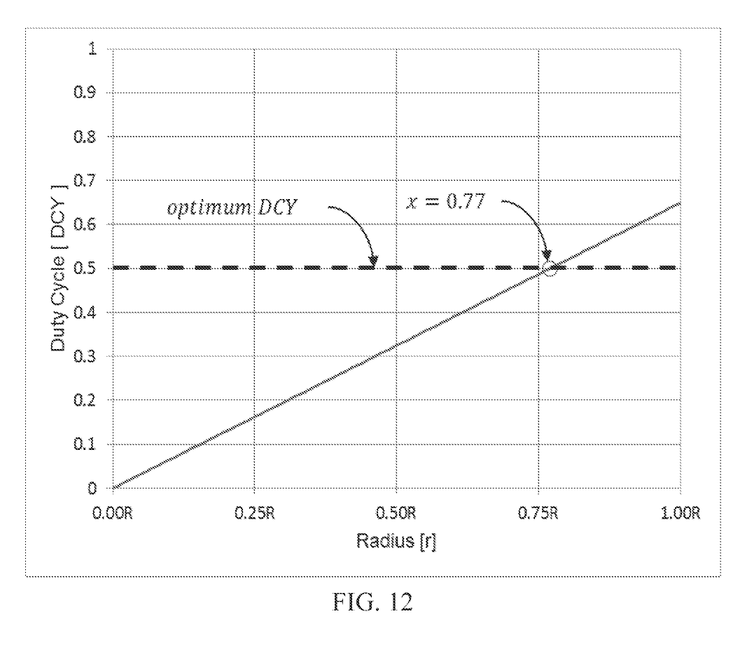

FIG. 11 shows a plot of the theoretical efficiency gains that can be achieved when the fabrication process transitions from a filling only method for the inner zones to a sidewall coating method for the outer zones (102-4). Depending upon where the transition point is placed between 0.5R and R, a global efficiency of 81% to 93% can be achieved.

Up to this point, to optimize efficiency the ALD coating thickness is equal to the outermost zone width (A=Δr). In a variant approach, by allowing the ALD coating thickness to be greater than the outermost zone width, total efficiency can be further optimized at the expense of perfect outermost zones. This concept is discussed in “Zone-Doubling Technique to Produce Ultrahigh-Resolution X-Ray Optics,” Jefimovs, K. et al., 31 Dec. 2007, Vol. 99, PHYSICAL REVIEW LETTERS 264801-1-264801-4.

To apply this concept to conventional ALD zone plates, the term, x, is added to the duty cycle vs. radius curve of ALD zone plates to describe a fraction of radius R where DCY equals 0.5. So now the duty cycle of an ALD zone plate can be described as

$$DCY ( r ) = \frac{0.5 r}{xR} .$$

Therefore if A=Δr, the value of x is 1. To determine the optimum value of x to maximize efficiency, we solve for the following argument:

$$arg {max}_{0 < x < 1} ( \frac{1}{π {R}^{2}} {\int }_{0}^{R} 2 π r {sin}^{2} ( π \frac{0.5 r}{xR} ) d r ) = 0.77$$

FIG. 12 plots the DCY for the zones 130 of conventional ALD zone plates with x=0.77. The DCY varies linearly with radius according to

$$DCY ( r ) = \frac{0.5 r}{xR}$$

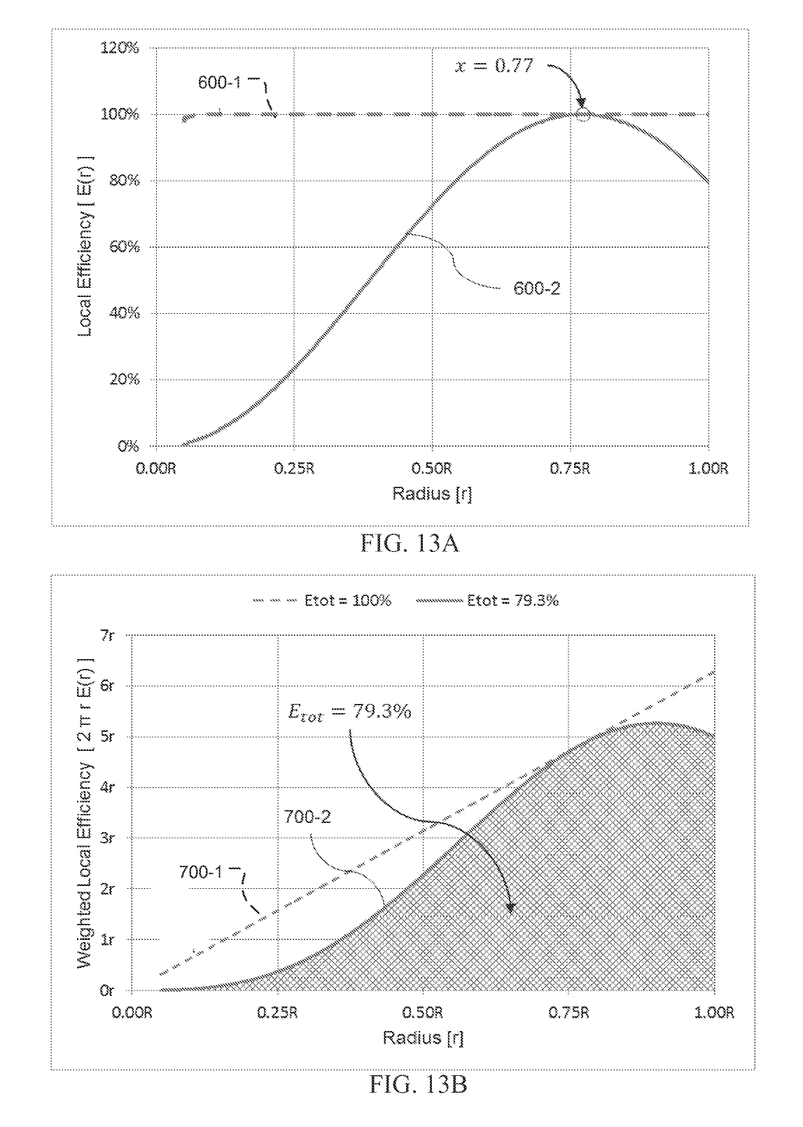

FIGS. 13A and 13B compare, respectively, the local diffraction efficiency E(r) and weighted efficiency Etot of the zones as a function of local radius for both the ideal zone plate of FIG. 1A and the conventional ALD zone plate of FIG. 3B. In both FIGS. 13A and 13B, the efficiency of the conventional ALD zone plate has been optimized using x=0.77.

FIG. 13A shows local efficiency E(r) curves 600-1 and 600-2, respectively, for an ideal zone plate and a conventional ALD zone plate that has been optimized for efficiency using x=0.77. For the conventional ALD zone plate at x=0.77, the local efficiency E(r) as a function of radius r is E(r)=sin²(πDCY(r)), which simplifies to

$$E ( r ) = {sin}^{2} ( π \frac{0.5 r}{0.77 R} ) .$$

FIG. 13B compares the total or weighted efficiency 700-1 and 700-2, respectively, for the ideal zone plate and a conventional ALD zone plate that has been optimized for efficiency using x=0.77. The total efficiency of zone plates, normalized over the area of the zone plate (πR²), in general, is given by

$${E}_{tot} = \frac{1}{π {R}^{2}} {\int }_{0}^{R} 2 π rE ( r ) d r .$$

When calculated for a conventional ALD zone plate that has been optimized for efficiency using x=0.77, the total efficiency is:

$${E}_{tot} = \frac{1}{π {R}^{2}} {\int }_{0}^{R} 2 π r {sin}^{2} ( π \frac{0.5 r}{xR} ) d r = 0.793 for x = 0.77 , or$$

$${E}_{tot} = 79.3 \% .$$

The concept of allowing the ALD coating thickness to be greater than the outermost zone width can be applied to both embodiments. With respect to the first embodiment, this theoretically provides the ability to better approach 100% efficiency with the current model. The ALD layer can be deposited beyond the point of substantially filling the annular channels 150, allowing the ALD layer to accumulate on the tops of the annular rings 110 and the annular channels 150. This is indicated by reference 144. However, the excess accumulation of material becomes substantial if the thickness A is selected to be substantially larger than the outermost zone width Δr, or A>>Δr.

The concept of optimizing the efficiency of the zone plate by allowing the ALD coating thickness to be greater than the outermost zone width can be applied similarly to the second embodiment to further improve total efficiency. To determine the optimum value of x to maximize efficiency, we solve for the following argument:

$$arg {max}_{0 < x < 1} ( \frac{1}{π {R}^{2}} {\int }_{0}^{0.5 xR} 2 π r {sin}^{2} ( π \frac{0.5 r}{0.5 xR} ) d r + \frac{1}{π {R}^{2}} {\int }_{0.5 xR}^{tR} 2 π r d r + \frac{1}{π {R}^{2}} {\int }_{tR}^{R} 2 π r {sin}^{2} ( π \frac{0.5 r}{xR} ) d r ) = 0.85 for t = 0.75$$

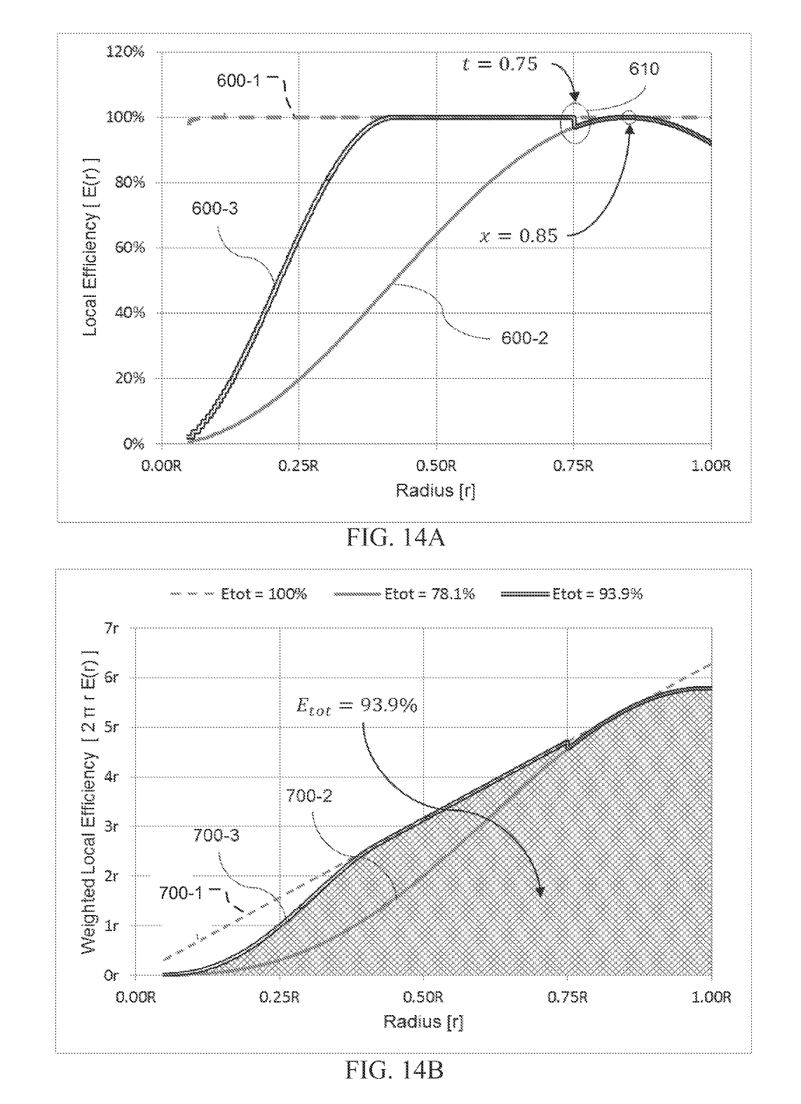

FIGS. 14A and 14B compare the diffraction efficiency, in FIG. 14A, and weighted diffraction efficiency, in FIG. 14B, for an ideal zone plate, a conventional ALD zone plate that has been optimized for efficiency using x=0.85, and an inventive ALD zone constructed according to the embodiment of FIG. 7C that also has been additionally optimized for efficiency using x=0.85.

FIG. 14A shows efficiency plots 600-1 for an ideal zone plate and 600-2 a conventional ALD zone plate that has been optimized for efficiency using x=0.85.

Efficiency curve 600-3 shows an efficiency plot for the embodiment of FIG. 7C that also has been additionally optimized for efficiency using x=0.85. Because the annular rings 110 of the template 160 are fabricated so a discontinuity arises when the zones change from being fabricated by filling the annular channels (sections 102-1 through 102-3) to merely coating the sidewalls of the annular rings (section 102-4), a jump 610 in the efficiency curve 600-3 occurs. The location of the discontinuity spike 610, tR, is determined by fabrication limitations and is experimentally inferred based on process capability. This example shows the transition point at 0.75R (t=0.75).

In a similar fashion, FIG. 14B shows weighted efficiency curves for the ideal zone plate 700-1, a conventional ALD zone plate 700-2 that has been optimized for efficiency using x=0.85, and a zone plate 700-3 constructed according to the second embodiment of FIG. 7C that has also been optimized for efficiency using x=0.85.

In FIGS. 14A and 14B, the local efficiency E(r) is:

$$E ( r ) = {sin}^{2} ( π DCY ( r ) )$$

$$E ( r ) = {sin}^{2} ( π \frac{0.5 r}{0.5 xR} ) where 0 < r < 0.5 xR$$

$$E ( r ) = 1 where 0.5 xR < r < tR$$

$$E ( r ) = {sin}^{2} ( π \frac{0.5 r}{xR} ) where tR < r < R$$

and the total efficiency, normalized over the area of the zone plate (πR²), Eₜₒₜ is:

$${E}_{tot} = \frac{1}{π {R}^{2}} {\int }_{0}^{0.5 xR} 2 π r {sin}^{2} ( π \frac{0.5 r}{0.5 xR} ) d r + \frac{1}{π {R}^{2}} {\int }_{0.5 xR}^{tR} 2 π r d r + \frac{1}{π {R}^{2}} {\int }_{tR}^{R} 2 π r {sin}^{2} ( π \frac{0.5 r}{xR} ) d r$$

$${E}_{tot} = 0.939 for x = 0.85 and t = 0.75 , or$$

$${E}_{tot} = 93.9 \%$$

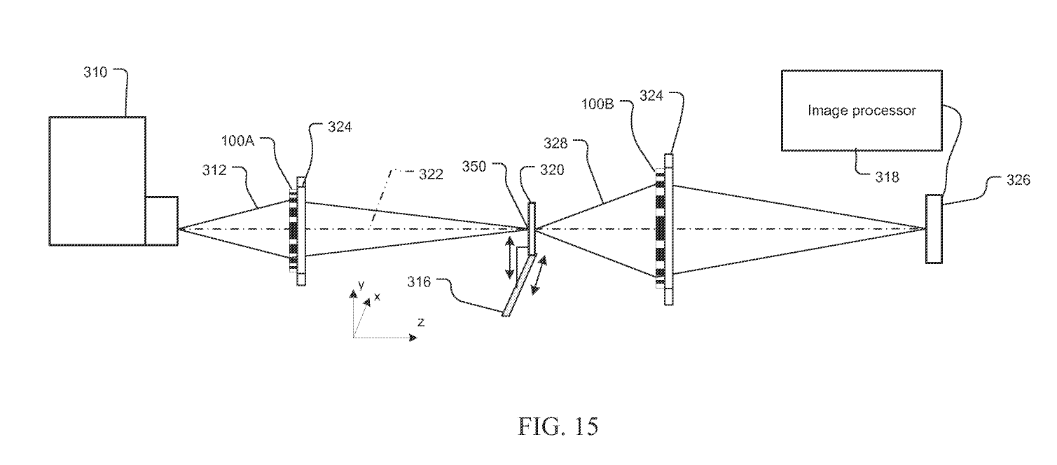

FIG. 15 shows an exemplary x-ray imaging system in which the zone plates constructed according to embodiments of the present invention can be used. In the example, the system uses possibly one zone plate 100A as a condenser and/or possibly a second zone plate 100B as an objective lens.

Zone plate 100A focuses x-rays from an x-ray source 310 onto a sample 350. Zone plate 100B accepts transmitted x-rays 328 transmitted through the sample 350, and focuses the transmitted x-rays 328 onto a detector 326.

The system has an x-ray source 310 that generates an x-ray beam 312 along the optical axis 322. In the example, the source is a beamline of a synchrotron x-ray generation facility. In other embodiments, lower power sources are used, such as laboratory sources. Such sources often generate x-rays by bombarding a solid target anode with energetic electrons. Specific examples include microfocus x-ray sources, liquid metal jet, and rotating anode sources.

The x-ray beam 312 is preferably a hard x-ray beam. In one embodiment, its energy is about 10 keV or higher. Generally, the beam's energy is between about 2 keV and 25 keV. These higher energies ensure good penetration through any intervening coating, e.g. fluid layer, onto the sample 350.

Zone plates 100A and 110B are held by respective holders 324. Zone plate 100A acts as a condenser and focuses the x-ray beam 112 from the source 310 unto the sample 350. A sample holder 320 is used to hold the sample 350 in the x-ray beam 312. The stage 316 scans the sample holder 320 in both the x and y axis directions, i.e., in a plane that is perpendicular to the axis 322 of the x-ray beam 312. In other examples, the stage 316 further rotates the sample 350 to obtain projections at different angles, which are often used for tomographic reconstruction in an image processor 318.

Zone plate 100B acts as an x-ray objective. It collects transmitted x-rays 328, from the sample 350 and focuses them onto the detector system 326. The detector system 326 is preferably a high-resolution, high-efficiency scintillator-coupled CCD (charge coupled device) camera system for detecting x-rays from the sample 350.

While this invention has been particularly shown and described with references to preferred embodiments thereof, it will be understood by those skilled in the art that various changes in form and details may be made therein without departing from the scope of the invention encompassed by the appended claims.

What is claimed is:

1. A method for fabricating a zone plate, comprising:
creating a template including annular rings that define annular channels; and
depositing a conformal coating layer to form zones of the zone plate on sidewalls of the annular rings, the conformal coating layer substantially filling at least some if not all of the annular channels to form wider zones.

2. The method of claim 1, wherein depositing the conformal coating layer to form the zones is accomplished using atomic layer deposition (ALD).

3. The method of claim 1, wherein a mark-to-space ratio of the annular rings increases towards a center of the zone plate.

4. The method of claim 1, further comprising using a mark-to-space ratio based on (Wᵣ−A):A for the annular rings of zones located at a local radius r from a center of the zone plate, r being up to ½ times a radius R of the zone plate, where A is a thickness of the conformal coating layer, and Wᵣ is an ideal zone width of each zone at the local radius r.

5. The method of claim 1, further comprising using a mark-to-space ratio of about 1:1 for the annular rings of zones located at a local radius r from the center of the zone plate, where r ranges from where Wᵣ=2A up to a radius R of the zone plate, where A is a thickness of an ALD conformal coating layer, and Wᵣ is an ideal zone width of each zone at the local radius r.

6. The method of claim 1, wherein a mark to space ratio of the annular rings is varied to allow zone widths from one times a thickness of the conformal coating layer up to and including two times the thickness of the conformal coating layer.

7. The method of claim 1, wherein a thickness of the conformal coating layer is on the order of a zone width of outermost zones or thicker.

8. The method of claim 1, further comprising substantially filling the annular channels with the conformal coating layer for all zones.

9. The method of claim 8, further comprising using a mark-to-space ratio of about 1:1 for the annular rings of outermost zones.

10. The method of claim 1, further comprising substantially filling the annular channels with the conformal coating layer for all zones except outermost zones.

11. The method of claim 10, further comprising using a mark-to-space ratio of about 1:3 for the annular rings of the outermost zones.

12. A zone plate, comprising:
a template including annular rings that define annular channels; and
a conformal coating layer on the template to form zones of the zone plate, the conformal coating layer substantially filling at least some if not all of the annular channels to form wider zones.

13. The zone plate of claim 12, wherein the conformal coating layer is deposited using atomic layer deposition (ALD).

14. The zone plate of claim 12, wherein a mark-to-space ratio of the annular rings increases towards a center of the zone plate.

15. The zone plate of claim 12, wherein the template uses a mark-to-space ratio based on (Wᵣ−A):A for the annular rings of zones located at a local radius r from the center of the zone plate, r being up to ½ times a radius R of the zone plate, where A is a thickness of an ALD conformal coating layer, and Wᵣ is an ideal zone width of each zone at the local radius r.

16. The zone plate of claim 12, wherein the template uses a mark-to-space ratio of about 1:1 for the annular rings of zones located at a local radius r from a center of the zone plate, where r ranges from where Wᵣ=2A up to a radius R of the zone plate, where A is a thickness of an ALD conformal coating layer, and Wᵣ is an ideal zone width of each zone at the local radius r.

17. The zone plate of claim 12, wherein a mark to space ratio of the annular rings is varied to enable formation of zones with zone widths from about one times a thickness of the conformal coating layer up to and including two times the thickness of the conformal coating layer.

18. The zone plate of claim 12, wherein a thickness of the conformal coating layer is on the order of a zone width of outermost zones or thicker.

19. The zone plate of claim 12, wherein the annular channels are substantially filled with the conformal coating layer for all zones.

20. The zone plate of claim 19, wherein the annular rings for outermost zones use a mark-to-space ratio of about 1:1.

21. The zone plate of claim 12, wherein the annular channels are substantially filled with the conformal coating layer for all zones except outermost zones.

22. The zone plate of claim 21, wherein the annular rings for the outermost zones use a mark-to-space ratio of about 1:3.

23. An x-ray imaging system, comprising:
a source of x-rays;
a detector for detecting the x-rays after interaction with a sample; and
a zone plate for directing the x-rays to the detector, wherein the zone plate, comprises a template including annular rings that define annular channels and a coating layer on the template to form zones of the zone plate, the conformal coating layer substantially filling at least some if not all of the annular channels to form wider zones.

24. A grating device, comprising:
a template including pillars that define channels; and
a conformal coating layer on the template to form a grating structures, the conformal coating layer substantially filling at least some if not all of the channels to form wider grating structures.
